(19) United States
(12) Patent Application Publication
(10) Pub. No.: US 2014/0261644 A1
(43) Pub. Date: Sep. 18, 2014

(54) METHOD AND STRUCTURE OF A MICROCHANNEL HEAT SINK DEVICE FOR MICRO-GAP THERMOPHOTOVOLTAIC ELECTRICAL ENERGY GENERATION

(71) Applicant: MTPV POWER CORPORATION, Austin, TX (US)

(72) Inventor: Eric Brown, Cambridge, MA (US)

(73) Assignee: MTPV POWER CORPORATION, Austin, TX (US)

(21) Appl. No.: 14/213,412

(22) Filed: Mar. 14, 2014

Related U.S. Application Data
(60) Provisional application No. 61/790,429, filed on Mar. 15, 2013.

(51) Int. Cl. H01L 31/04

(52) U.S. Cl. CPC H01L 31/0406
USPC 136/253

(57) ABSTRACT

A method and device for maintaining a low temperature of a cold-side emitter for improving the efficiency of a sub-micron gap thermophotovoltaic cell structure. A thermophotovoltaic cell structure may comprise multiple layers compressed together by a force mechanism so that the sub-micron gap dimension is relatively constant although the layer boundaries may not be substantially flat compared to the relatively constant sub-micron dimension. The layered structure includes a hot side thermal emitter having a surface separated from a photovoltaic cell surface by a sub-micron gap having a dimension maintained by spacers. The surface of the photovoltaic cell opposite the sub-micron gap is compressibly positioned against a surface of microchannel heat sink and the surface of the microchannel heat sink opposite the photovoltaic cell is compressibly positioned against a flat metal plate layer and a compressible layer.

### BACKGROUND

The present invention relates to micron-gap thermal photovoltaic (MTPV) technology for conversion of radiated thermal power to electrical power. While the use of micron-gaps and submicron-gaps between a hot-side emitter and a cold side collector enable an increase in power density of an order of magnitude over more conventional thermovoltaic devices, there may also be a commensurate increase in temperature of the cold-side collector due to absorption of out-of-band thermal radiation by the cold side collector. In order to maintain efficiency of the cold-side collector and uniform gap separation between the hot-side emitter and the cold-side collector, various means have been employed to maintain the cold-side collector at a reduced temperature. The present invention relates more particularly to a novel method and device for maintaining a relatively low temperature of the cold-side collector through the use of a microchannel heat sink employing a liquid coolant.

### SUMMARY

The present invention provides a novel method and device for maintaining a low temperature of a cold-side collector for improving the efficiency of a sub-micron gap thermophotovoltaic cell structure. An embodiment of a typical sub-micron gap thermophotovoltaic cell structure according to the present invention may comprise multiple layers compressed together so that the sub-micron gap dimension is relatively constant although the layer boundaries may not be substantially flat compared to the relatively constant sub-micron dimension. The layered structure may comprise a hot side thermal emitter having a surface separated from a photovoltaic cell surface by a sub-micron gap having a dimension maintained by spacers. The surface of the photovoltaic cell opposite the sub-micron gap is compressibly positioned against a surface of a microchannel heat sink and the surface of the microchannel heat sink opposite the photovoltaic cell is compressibly positioned against a flat rigid plate layer separated by a compressible layer or “sponge”. Forcibly positioned against the side of the flat rigid plate opposite the compressible layer is a force mechanism for compressing the layers of the sub-micron gap photovoltaic cell structure into close contact with one another in order to maintain a uniform gap dimension between the surface of the hot side thermal emitter and the opposing surface of the photovoltaic cell. The force mechanism may be, for example, a piezoelectric force transducer, or a pneumatic or hydraulic chamber containing a fluid maintained under a controllable pressure by an external source. Note that a piezoelectric transducer array may provide an active compressing force in a Z-dimension perpendicular to the surfaces of the substrate layers, as described above, and passive forces in an X-dimension and a Y-dimension for counteracting irregular surfaces, while minimizing in-plane stresses on the layers.

The microchannel heat sink includes an input manifold for receiving a suitable coolant from an external source. The coolant is forced under pressure from the input manifold through multiple microchannels beneath a surface of the microchannel heat sink where the coolant absorbs heat energy. The heated coolant is then passed to an exhaust manifold where it is returned to the external source for cooling and further processing.

The benefits of the microchannel heat sink method described above over prior methods are that a liquid metal layer is no longer required, mechanical bellows are eliminated, and the effect of fluid flow forces on the stack are eliminated. Furthermore. the need to regulate liquid metal pressure, in accordance with axial compressive force, is eliminated, reducing hardware requirements and complexity.

This Summary is provided to introduce a selection of concepts in a simplified form that are further described below in the Detailed Description. This Summary is not intended to identify all key or essential features of the claimed matter, nor is it intended to be used to limit the scope of the claimed subject matter.

### BRIEF DESCRIPTION OF THE DRAWINGS

These and other features, aspects and advantages of the present invention will become better understood with regard to the following description and accompanying drawings wherein:

FIG. 1 illustrates an embodiment of a sub-micron gap thermophotovoltaic cell structure according to the present invention;

FIG. 2 is a perspective view of an embodiment of the fabrication of a microchannel heat sink structure according to the present invention; and

FIG. 3 is a perspective view of an embodiment of a microchannel heat sink structure according to the present invention.

### DETAILED DESCRIPTION OF THE DRAWINGS

Considering FIG. 1, FIG. 1 illustrates an embodiment of a sub-micron gap thermophotovoltaic cell structure 100 according to the present invention. The structure comprises multiple substrate layers, which are generally non-flat on the micron scale, forcibly positioned against one another and compressibly confined within an enclosure 195 to maintain a relatively constant sub-micron gap dimension 112 between a surface of a hot side thermal emitter 110 and an opposing surface of a photovoltaic cell 120. Spacers 115 are provided to help maintain a suitable sub-micron gap dimension. A channel plate 130 of a microchannel heat sink 125 is compressed against a surface of the photovoltaic cell 120 opposite the sub-micron gap 112. The microchannel heat sink 125 comprises the channel plate 130 and an affixed containment plate 135. The containment plate 135 includes an input coolant connector 145 for providing an inflow of coolant 190 to an input manifold of the microchannel heat sink 125 and an exhaust coolant connector 140 for providing an outflow of coolant 175 from an exhaust manifold of the microchannel heat sink 125. The channel plate 130 includes the input manifold, multiple microchannels between the input and exhaust manifold, and the exhaust manifold, as described below.

An external surface of the containment plate 135 is compressibly positioned against a flat rigid plate 155 separated by a compressible layer 150. The compressive layer 150 needs to compress enough to provide enough force to make all layers, including the microchannel heat sink 125, take on a common shape, consistent with the enclosure. The heat sink 125 is made thin to allow for bending on the level of tens of microns. The compressible layer 150 will not have uniform thickness when compressed due to the non-flatness of the other layers. Therefore, the stiffness and thickness of the compressible layer 150 are carefully chosen to minimize pressure variation across the gap 112. For example, the compressible layer 150 may be 1000 micro thick foam that compresses an average of 100 microns due to the application of force. Also, if the thickness variation of the compressible layer 150 is 10 microns due to surface variations of the layers being compressed, then there would be 10% variation in pressure applied to the microchannel heat sink. Further reduction in the compressive stiffness of the foam would reduce this pressure variation.

A force mechanism 160 is compressibly positioned on the surface of the rigid plate opposite the compressible layer 150. The force mechanism 160 applies a compressing force against the other layers for maintaining a relatively constant sub-micron gap dimension in spite of non-uniform surface flatness of the substrate layers. An input connector 170 may be provided for providing compressing energy 185 to the force mechanism 160 and an output connector 165 may be provided as a return 180 for the compressing energy from the force mechanism 160. If, for example, the force mechanism 160 is implemented with piezoelectric transducers, the connectors 170, 165 may be electrical connections. If the force mechanism 160 is a pneumatic implementation, the connectors 170, 165 may be pneumatic connectors.

Turning to FIG. 2, FIG. 2 is a perspective view of an embodiment of the fabrication 200 of a microchannel heat sink structure according to the present invention. FIG. 2 includes the channel plate 220 (130 in FIG. 1) and the containment plate 260 (135 in FIG. 1). FIG. 2 illustrates an input manifold 240 that receives coolant from a coolant source and supplies the coolant to the microchannels 230 connected to the exhaust manifold 210. In passing through the microchannels 230, the coolant absorbs heat and is collected in the exhaust manifold 210 for return, cooling and processing at the coolant source. The containment plate 260 includes an input orifice 270 for connecting the coolant supply to the input manifold 240 and an exhaust orifice 250 for connecting coolant return from the exhaust manifold 210. Other embodiments may have multiple orifices on the inlet and outlet sides to mitigate mechanical stress.

The channel plate 220 may be fabricated from silicon and micro-machined to provide the input manifold 240, the microchannels 230 and the exhaust manifold 210, using conventional photolithography and etching techniques. The containment plate 260 may also be fabricated from silicon, and bonded to the channel plate 220 using adhesives such as epoxy or other wafer bonding techniques such as glass frit and thermal compression.

Turning to FIG. 3, FIG. 3 is a perspective view an embodiment of a microchannel heat sink structure 300 according to the present invention. Although silicon wafers are not usually transparent, FIG. 3 depicts the channel plate 320 as a transparent structure to better illustrates the structural details of the microchannel heat sink 300. FIG. 3 shows the channel plate 320 bonded to the containment plate 360. Coolant fluid 390 enters the input coolant connector 385 through the coolant input orifice 370 and into the input manifold 340. The input manifold 340 distributes the coolant through the microchannels 330 to the exhaust manifold 310. The coolant is heated as it passes through the microchannels 330. The heated coolant fluid 380 is accepted by the exhaust manifold 310 and provided to the exhaust coolant connector 375 via the coolant exhaust orifice 350 for return to the coolant source for processing.

Although the subject matter has been described in language specific to structural features and methodological acts, it is to be understood that the subject matter defined in the appended claims is not necessarily limited to the specific features or acts described above. Rather, the specific features and acts described above are disclosed as example forms of implementing the claims.

1. A layered structure for maintaining a uniform sub-micron gap and a low temperature of a cold-side photovoltaic collector of a thermophotovoltaic cell, comprising:
a layered structure including a hot side substrate separated from a cold side photovoltaic cell by a sub-micron gap maintained with spacers, a microchannel heat sink, a compressible layer, a flat rigid plate, and a force mechanism;
the layered structure housed within an enclosure;
the hot side substrate and the force mechanism maintained in rigid positional relationship with one another by the enclosure; and
a compressing force maintained by the force mechanism on layers within the enclosure between the hot side substrate and the force mechanism for maintaining a uniform sub-micron gap and effective thermal conduction between the photovoltaic cell and the microchannel heat sink.

2. The structure of claim 1, wherein the microchannel heat sink is compressibly positioned against the photovoltaic cell by the compressible layer, the flat rigid plate and the force mechanism.

3. The structure of claim 1, wherein the microchannel heat sink may assume a shape of the enclosure.

4. The structure of claim 1, wherein a structural characteristic of the microchannel heat sink is selected from the group consisting of rigid, semi-rigid and flexible.

5. The structure of claim 1 wherein the compressible layer minimizes pressure variations on the photovoltaic cell, the hot side layer and the spacers in the sub-micron gap.

6. The structure of claim 1 wherein the microchannel heat sink includes:
an input coolant connector connected to a coolant input manifold via a coolant orifice;
a coolant exhaust manifold connected to a coolant exhaust connector via an exhaust coolant manifold; and
a channel plate between the input coolant manifold and the coolant exhaust manifold, the channel plate having multiple microchannels for conducting coolant between the input coolant manifold and the coolant exhaust manifold.

7. The structure of claim 1, wherein the microchannel heat sink includes a silicon channel plate bonded to a silicon containment plate, the channel plate fabricated from silicon and micro-machined to provide an input manifold, an exhaust manifold and microchannels between the input manifold and the exhaust manifold.

8. The structure of claim 1, wherein the force mechanism is selected from the group consisting of a piezoelectric transducer, a pneumatic actuator and a pressure regulator.

9. A method for maintaining a uniform sub-micron gap and a low temperature of a cold-side photovoltaic collector of a thermophotovoltaic cell, comprising:
forming a layered structure including a hot side substrate separated from a cold side photovoltaic cell by a sub-micron gap maintained with spacers, a microchannel heat sink, a compressible layer, a flat rigid plate, and a force mechanism;
enclosing the layered structure within an enclosure;
maintaining the hot side substrate and the force mechanism in rigid positional relationship with one another by the enclosure; and
producing a compressing force by the force mechanism on layers within the enclosure between the hot side substrate and the force mechanism for maintaining a uniform sub-micron gap and effective thermal conduction between the photovoltaic cell and the microchannel heat sink.

10. The method of claim 9 further comprising compressibly positioning the microchannel heat sink against the photovoltaic cell by the compressible layer, the flat rigid plate and the force mechanism.

11. The method of claim 9 further comprising enabling the microchannel heat sink to assume a shape of the enclosure.

12. The method of claim 9 further comprising selecting a structural characteristic of the microchannel heat sink from the group consisting of rigid, semi-rigid and flexible.

13. The method of claim 9 further comprising minimizing pressure variations on the photovoltaic cell, the hot side layer and the spacers in the sub-micron gap by the compressible layer.

14. The method of claim 9 further comprising;
connecting an input coolant connector to a coolant input manifold via a coolant orifice in the microchannel heat sink;
connecting a coolant exhaust manifold to a coolant exhaust connector via an exhaust coolant manifold in the microchannel heat sink; and
positioning a channel plate between the input coolant manifold and the coolant exhaust manifold, the channel plate having multiple microchannels for conducting coolant between the input coolant manifold and the coolant exhaust manifold.

15. The method of claim 9, further comprising including a silicon channel plate bonded to a silicon containment plate to form a microchannel heat sink, fabricating the channel plate from silicon and micro-machining it to provide an input manifold, an exhaust manifold and microchannels between the input manifold and the exhaust manifold.

16. The method of claim 9, further comprising selecting the force mechanism from the group consisting of a piezoelectric transducer, a pneumatic actuator and a pressure regulator.

17. A layered structure for maintaining a uniform sub-micron gap and a low temperature of a cold-side photovoltaic collector of a thermophotovoltaic cell, comprising:
a thermal emitter surface of a hot side substrate separated from a thermal collecting surface of a photovoltaic cell by a sub-micron gap maintained by spacers;
a first surface of a microchannel heat sink compressibly positioned against a surface of the photovoltaic cell surface opposite the thermal collecting surface of the photovoltaic cell;
a second surface of the microchannel heat sink opposite the first surface of the microchannel heat sink compressibly positioned against a first surface of a compressible layer;
a second surface of the compressible layer opposite the first surface of the compressible layer compressibly positioned against a first surface of a flat rigid plate;
a second surface of the flat rigid plate opposite the first surface of the flat rigid plate compressibly positioned against a first surface of a force mechanism;
a thermal collector surface of the hot side substrate opposite the hot side thermal emitter surface maintained in a rigid positional relationship with a second surface of the force mechanism opposite the first surface of the force mechanism by an enclosure; and
a compressing force maintained by the force mechanism on the layers within the enclosure between the hot side thermal collector surface and the second surface of the force mechanism for maintaining a uniform sub-micron gap and effective thermal conduction between the photovoltaic cell and the microchannel heat sink.

18. A layered structure for maintaining a uniform sub-micron gap and a low temperature of a cold-side collector of a thermal-to-electric conversion cell, comprising:
a layered structure including a hot side substrate separated from a cold side cell by a sub-micron gap maintained with spacers, a microchannel heat sink, a compressible layer, a flat rigid plate, and a force mechanism;
the layered structure housed within an enclosure;
the hot side substrate and the force mechanism maintained in rigid positional relationship with one another by the enclosure; and
a compressing force maintained by the force mechanism on layers within the enclosure between the hot side substrate and the force mechanism for maintaining a uniform sub-micron gap and effective thermal conduction between the cell and the microchannel heat sink.
